(19) United States
(12) Patent Application Publication
(10) Pub. No.: US 2009/0159882 A1
(43) Pub. Date: Jun. 25, 2009

(54) Test Pattern of Semiconductor Device and Manufacturing Method Thereof

(76) Inventor: Hyung Jin Park, Eumseong-gun (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/267,742

(22) Filed: Nov. 10, 2008

(30) Foreign Application Priority Data
Dec. 21, 2007 (KR) 10-2007-0135893

(51) Int. Cl. H01L 21/336; H01L 29/78

(52) U.S. Cl. 257/48; 438/197; 257/E29.255; 257/E21.409

(57) ABSTRACT

A test pattern of a semiconductor device and manufacturing method thereof are provided. The test pattern can include an isolation layer on a semiconductor substrate to define an active area, a gate electrode on the active area, and a source/drain area at a first area of the active area between the gate electrode and the isolation layer, a third area of the active area spaced apart from the gate electrode, and a second area of the active area electrically connecting the first area with the third area.

### CROSS-REFERENCE TO RELATED APPLICATION

The present application claims the benefit under 35 U.S.C. § 119 of Korean Patent Application No. 10-2007-0135893, filed Dec. 21, 2007, which is hereby incorporated by reference in its entirety.

### BACKGROUND

As semiconductor devices are manufactured in smaller and smaller sizes, various parasitic effects are generated. Such parasitic effects have become some of the main parameters to be considered in the semiconductor manufacturing process.

Meanwhile, the distance between a gate electrode of an active area and an isolation layer is also an important parameter in a transistor. As the distance is reduced, stress is increased due to the different materials of the active area and the isolation layer, causing variation in electron mobility in a channel.

FIG. 1 is a cross-sectional view showing a conventional test pattern for inspecting characteristics of a transistor.

Referring to FIG. 1, an isolation layer 10 is formed on a semiconductor substrate 100 to define an active area. A gate electrode 20 is formed on the active area, and source/drain areas 30 are formed at both sides of the gate electrode 20.

An interlayer dielectric layer 50 is formed on the semiconductor substrate 100 including the gate electrode 20, and a contact plug 40 is formed by passing through the interlayer dielectric layer 50 to be electrically connected with the source/drain areas 30. The contact plug 40 is electrically connected with a metal interconnection 60.

The test pattern shown in FIG. 1 is designed such that the distance between the gate electrode 20 and the isolation layer 10 is reduced, so that various characteristics, including stress due to the difference between materials of the active area and the isolation layer 10, can be verified.

However, since the contact plug 40 is disposed between the gate electrode 20 and the isolation layer 10 in the conventional test pattern, the distance between the gate electrode 20 and the isolation layer 10 cannot be smaller than the size of the contact plug 40.

Thus, it is impossible to verify certain characteristics according to variation in the distance between the gate electrode 20 and the isolation layer 10.

### BRIEF SUMMARY

Embodiments of the present invention provide a test pattern of a semiconductor device and a manufacturing method thereof. The test pattern can be used for verifying characteristics of a transistor when the distance between a gate electrode and an isolation layer is short.

In an embodiment, a test pattern of a semiconductor device can comprise: an isolation layer on a semiconductor substrate to define an active area, a gate electrode on the active area, and a source/drain area at a first area of the active area between the gate electrode and the isolation layer, a third area of the active area spaced apart from the gate electrode such that a portion of the isolation layer is between the third area and the gate electrode, and a second area of the active area electrically connecting the first area with the third area.

In another embodiment, a method for manufacturing a test pattern of a semiconductor device can comprise: forming an isolation layer on a semiconductor substrate to define an active area, forming a gate electrode on the active area, and forming a source/drain area on the active area at a first area of the active area between the gate electrode and the isolation layer, a third area of the active area spaced apart from the gate electrode such that a portion of the isolation layer is between the third area and the gate electrode, and a second area of the active area electrically connecting the first area with the third area.

### BRIEF DESCRIPTION OF THE DRAWINGS

FIG. 1 is a cross-sectional view showing a conventional test pattern for inspecting characteristics of a transistor.

FIG. 2 is a plan view of a test pattern of a semiconductor device according to an embodiment of the present invention.

FIG. 3 is a cross-sectional view of a test pattern of a semiconductor device according to an embodiment of the present invention.

FIGS. 4 to 6 are cross-sectional views showing a method for manufacturing a test pattern of a semiconductor device according to an embodiment of the present invention.

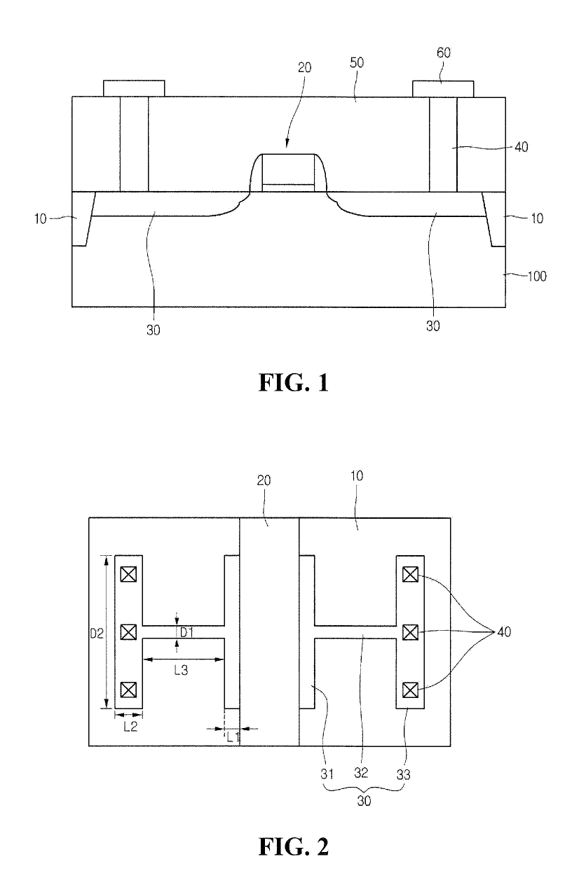

### DETAILED DESCRIPTION

Hereinafter, a test pattern of a semiconductor device and a manufacturing method thereof according to embodiments will be described in detail with reference to the accompanying drawings.

When the terms “on” or “over” or “above” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

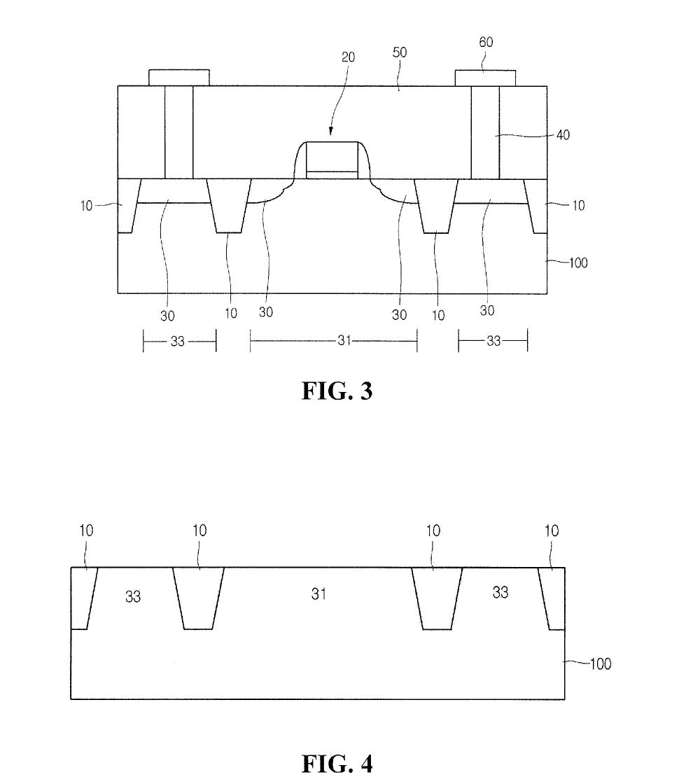

FIG. 2 is a plan view of a test pattern of a semiconductor device according to an embodiment, and FIG. 3 is a cross-sectional view of the test pattern of the semiconductor device.

Referring to FIGS. 2 and 3, the test pattern of the semiconductor device can include an isolation layer 10 formed on a semiconductor substrate 100 to define an active area, and a gate electrode 20 in the active area. The gate electrode can include a gate insulating layer and a sidewall spacer.

Source/drain areas 30 can be formed at both sides of the gate electrode 20.

The source/drain areas 30 can be disposed at a first area 31 between the gate electrode 20 and the isolation layer 10, a third area 33 spaced apart from the gate electrode 20, and a second area 32 connecting the first area 31 with the third area 33.

The first area 31 can be used for verifying transistor characteristics when the distance between the gate electrode 20 and the isolation layer 10 is short, and the third area 33 can provide an area for forming a contact plug 40. The second area 32 can electrically connect the First area 31 with the third area 33.

In the test pattern of the semiconductor device according to the embodiment, the third area 33 of the source/drain area 30, in which the contact plug 40 is formed, can be disposed spaced apart from the gate electrode 20 such that a portion of the isolation layer 10 is between the gate electrode 20 and the third area 33. Thus, the distance between the gate electrode 20 and the isolation layer 10 can be shortened.

Additionally, in an embodiment, the source/drain area 30 of the first area 31 between the gate electrode 20 and the isolation layer 10 can have a length L1 of from about 0.08 μm to about 0.15 μm. The third area 33 can have a length L2 of about 0.3 μm longer than the length L1 of the source/drain area 30 of the first area 31. Also, the second area 32 can have a length L3 of from about 0.3 μm to about 0.4 μm.

In a further embodiment, the second area 32 can have a width D1 that is smaller than a width D2 of the third area 33. For example, the second area 32 can have a width D1 that is from about 10% to about 20% of the width D2 of the third area 33. That is, the width D2 of the third area 33 can be from about 5 to about 10 times larger than the width D1 of the second area 32.

In certain embodiments, the second area 32 can be silicided to reduce resistance components.

FIGS. 4 to 6 are cross-sectional views showing a method for manufacturing a test pattern of a semiconductor device according to an embodiment of the present invention.

Referring to FIG. 4, the isolation layer 10 can be formed on the semiconductor substrate 100 to define the active area.

The isolation layer 10 can protrude in the direction of the active area so that the active area can be divided into the first area 31, where the gate electrode 20 can be formed, and the third area 33.

The isolation layers 10 dividing the first area 31 from the third area 33 are spaced from each other, so that the first area 31 can be connected with the third area 33 through a second area 32 (see FIG. 2).

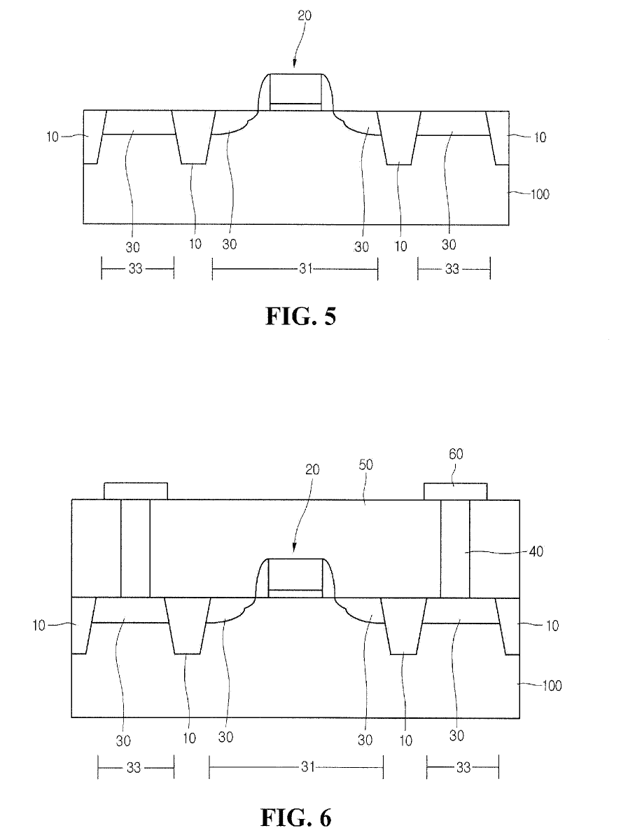

Referring to FIG. 5, the gate electrode 20 and the source/drain areas 30 can be formed on the active area of the first area 31. The gate electrode 20 can be formed through any suitable process known in the art. For example, a gate insulating layer and a polysilicon layer can be formed and patterned using photolithography and etching processes. Also, an impurity implantation process can be performed to form the source/drain areas 30.

Referring to FIG. 6, an interlayer dielectric layer 50 can be formed on the semiconductor substrate 100 including the gate electrode 20, and the contact plug 40 can be formed. In an embodiment, the contact plug 40 can be formed by forming a via hole in the interlayer dielectric layer 50 and then filling the via hole with a metal material.

A metal interconnection 60 can be formed on the interlayer dielectric layer 50 and electrically connected with the contact plug 40. Although not shown, a contact plug can be formed for contacting the gate electrode 20.

According to embodiments of the present invention, the contact plugs 40 can be formed on the source/drain areas 30 of the third area 33, which is disposed outward from the isolation layer 10 defining the first area 31. Thus, transistor characteristics can be tested when the distance between the gate electrode 20 and the isolation layer 10 is short, so that performance of the transistor can be more accurately verified.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A test pattern of a semiconductor device, the test pattern comprising:
an isolation layer on a semiconductor substrate to define an active area;
a gate electrode on the active area; and
a source/drain area at a side of the gate electrode; wherein the source/drain area is disposed at a first area of the active area between the gate electrode and the isolation layer, a third area of the active area spaced apart from the gate electrode such that a portion of the isolation layer is between the third area and the gate electrode, and a second area of the active area electrically connecting the first area with the third area.

2. The test pattern according to claim 1, further comprising a contact plug connected with the source/drain area of the third area.

3. The test pattern according to claim 1, wherein the first area has a length shorter than a length of the third area.

4. The test pattern according to claim 1, wherein the second area has a width smaller than a width of the first area.

5. The test pattern according to claim 1, wherein the second area has a width smaller than a width of the third area.

6. The test pattern according to claim 1, wherein the source/drain area at the first area has a length of from about 0.08 μm to about 0.15 μm.

7. The test pattern according to claim 6, wherein the third area has a length of about 0.3 μm longer than the length of the source/drain area of the first area.

8. The test pattern according to claim 1, wherein the second area has a length of from about 0.3 μm to about 0.4 μm.

9. The test pattern according to claim 1, wherein a width of the third area is from about 5 times to about 10 times larger than a width of the second area.

10. A method for manufacturing a test pattern of a semiconductor device, comprising:
forming an isolation layer on a semiconductor substrate to define an active area;
forming a gate electrode on the active area; and
forming a source/drain area at a first area of the active area between the gate electrode and the isolation layer, a third area of the active area spaced apart from the gate electrode such that a portion of the isolation layer is between the third area and the gate electrode, and a second area of the active area electrically connecting the first area with the third area.

11. The method according to claim 10, further comprising forming a contact plug connected with the source/drain area of the third area.

12. The method according to claim 10, wherein the first area has a length shorter than a length of the third area.

13. The method according to claim 10, wherein the second area has a width smaller than a width of the first area.

14. The method according to claim 10, wherein the second area has a width smaller than a width of the third area.

15. The method according to claim 10, wherein the source/drain area at the first area has a length of from about 0.08 μm to about 0.15 μm.

16. The method according to claim 15, wherein the third area has a length of about 0.3 μm longer than the length of the source/drain area at the first area.

17. The method according to claim 10, wherein the second area has a length of from about 0.3 μm to about 0.4 μm.

18. The method according to claim 10, wherein a width of the third area is from about 5 times to about 10 times larger than a width of the second area.
